(19) United States
(12) Patent Application Publication
(10) Pub. No.: US 2025/0221193 A1
(43) Pub. Date: Jul. 3, 2025

(54) DISPLAY DEVICE AND METHOD OF MANUFACTURING THE SAME

(71) Applicant: Samsung Display Co., LTD., Yongin-si (KR)

(72) Inventors: Hyun Eok SHIN, Yongin-si (KR); Dong Min LEE, Yongin-si (KR); Ju Hyun LEE, Yongin-si (KR)

(21) Appl. No.: 18/769,194

(22) Filed: Jul. 10, 2024

(30) Foreign Application Priority Data
Jan. 3, 2024 (KR) 10-2024-0001027

(51) Int. Cl. H10K 59/131; H10K 59/12; H10K 59/80; H10K 71/60; H10K 102/10

(52) U.S. Cl. CPC H10K 59/131; H10K 59/1201; H10K 59/80518; H10K 59/80522; H10K 71/60; H10K 2102/101

(57) ABSTRACT

A display device according to one or more embodiments of the disclosure includes a base layer, an insulating layer above the base layer, and defining a first trench and a second trench, a connection electrode at least partially located in the first trench, a reflective electrode at least partially located in the second trench, an intermediate layer above the reflective electrode, a first electrode above the intermediate layer, a light-emitting unit above the first electrode, a partition wall adjacent to the light-emitting unit, and at least partially overlapping the connection electrode in plan view, and an auxiliary electrode above the light-emitting unit, and electrically connected to the connection electrode.

### CROSS-REFERENCE TO RELATED APPLICATION

The present application claims priority to, and the benefit of, Korean Patent Application No. 10-2024-0001027, filed on Jan. 3, 2024, in the Korean Intellectual Property Office, the entire disclosure of which is incorporated herein by reference.

### BACKGROUND

### 1. Field

The disclosure relates to a display device and a method of manufacturing the same.

### 2. Description of the Related Art

As information technology develops, the importance of a display device as a connection medium between a user and information is being emphasized. For example, as the demand for high quality display devices increases, active discussions are underway about a display device including a light-emitting element having a micro or nano scale.

The display device may include a partition wall defining an area in which a light-emitting unit is located. In the display device including the light-emitting element having a micro or nano scale, a gap between partition walls may be narrowed to a micro or nano scale. As the gap between the partition walls narrows, the risk of leakage current occurring between the partition walls may increase.

### SUMMARY

An aspect of the disclosure provides a display device that can reduce the risk of leakage current occurring between partition walls and a method of manufacturing the same.

Another aspect of the disclosure provides a display device in which the manufacturing process of the display device can be simplified and a method of manufacturing the same.

Another aspect of the disclosure provides a display device in which a cathode electrode of a light-emitting element and a power source line can be stably electrically connected and a method of manufacturing the same.

A display device according to one or more embodiments of the disclosure may include a base layer, an insulating layer above the base layer, and defining a first trench and a second trench, a connection electrode at least partially located in the first trench, a reflective electrode at least partially located in the second trench, an intermediate layer above the reflective electrode, a first electrode above the intermediate layer, a light-emitting unit above the first electrode, a partition wall adjacent to the light-emitting unit, and at least partially overlapping the connection electrode in plan view, and an auxiliary electrode above the light-emitting unit, and electrically connected to the connection electrode.

The intermediate layer may include one or more of silicon oxide (SiOx) or silicon nitride (SiNx).

The intermediate layer may contact the reflective electrode, wherein a side surface of the intermediate layer is surrounded by a side surface of the reflective electrode in plan view.

A surface of the intermediate layer and a surface of the connection electrode may be at a same plane.

The reflective electrode and the connection electrode may include a same material.

The reflective electrode and the connection electrode may include silver (Ag).

The partition wall may include a first partition wall layer, and a second partition wall layer above the first partition wall layer and protruding outwardly further than the first partition wall layer.

The second partition wall layer may protrude outwardly further from the first partition wall layer by about 0.3 μm to about 1 μm.

The first partition wall layer may include aluminum (Al), wherein the second partition wall layer includes titanium (Ti).

The light-emitting unit may be separated from the partition wall, and may not contact the first partition wall layer.

The auxiliary electrode may at least partially overlap the connection electrode in plan view.

The auxiliary electrode may include transparent conductive oxide (TCO) material.

The display device may further include a second electrode above the light-emitting unit, and electrically connected to the partition wall by the auxiliary electrode.

The second trench may have a second trench height, wherein the first trench has a first trench height that is lower than the second trench height.

A difference between the second trench height and the first trench height may be about 500 Å to about 1000 Å.

A method of manufacturing a display device according to one or more embodiments of the disclosure may include forming an insulating layer defining a first trench and a second trench above a base layer, forming a connection electrode at least partially located in the first trench, forming a reflective electrode at least partially located in the second trench, forming an intermediate layer above the reflective electrode, forming a first electrode above the intermediate layer, forming a partition wall above the connection electrode, and overlapping the connection electrode in plan view, forming a light-emitting unit above the first electrode, and forming an auxiliary electrode above the light-emitting unit, and electrically connected to the connection electrode.

Forming the reflective electrode, forming the connection electrode, and forming the intermediate layer may include depositing a base reflective electrode above a base insulating layer, depositing a base intermediate layer above the base reflective electrode, and polishing at least a portion of the base insulating layer, the base reflective electrode, and the base intermediate layer, to form the reflective electrode, the connection electrode, and the intermediate layer.

The polishing may include polishing the base reflective electrode to form the reflective electrode and the connection electrode, and polishing the base intermediate layer to form the intermediate layer, wherein a surface of the intermediate layer and a surface of the connection electrode are at a same plane.

The forming the partition wall on the connection electrode may include forming a first partition wall layer above the connection electrode, and forming a second partition wall layer above the first partition wall layer, and protruding outwardly further than the first partition wall layer.

The method may further include forming a second electrode above the light-emitting unit, and electrically connected to the partition wall by the auxiliary electrode.

### BRIEF DESCRIPTION OF THE DRAWINGS

The accompanying drawings, which are included to provide a further understanding of the present disclosure, and are incorporated in and constitute a part of this specification, illustrate embodiments of the present disclosure, and, together with the description, serve to explain aspects of the present disclosure.

FIG. 1 is a schematic plan view illustrating a display device according to one or more embodiments.

FIG. 2 is a schematic cross-sectional view illustrating the display device according to one or more embodiments.

FIG. 3 is a schematic cross-sectional view enlarging an area of FIG. 2.

FIG. 4 is a cross-sectional view illustrating one or more embodiments of a light-emitting element of FIG. 2.

FIG. 5 is a cross-sectional view illustrating one or more other embodiments of the light-emitting element of FIG. 2.

FIG. 6 is a schematic block diagram illustrating an electrical connection structure for the light-emitting element according to one or more embodiments.

FIG. 7 is a flowchart illustrating a method of manufacturing a display device according to one or more embodiments.

FIGS. 8 to 14 are schematic cross-sectional views illustrating the method of manufacturing the display device according to one or more embodiments.

FIG. 15 is a block diagram schematically illustrating a display system according to one or more embodiments.

FIGS. 16 and 17 are perspective views schematically illustrating an application example of the display system of FIG. 15.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

The disclosure relates to a display device and a method of manufacturing the same. Hereinafter, a display device and a method of manufacturing the same according to embodiments will be described with reference to the accompanying drawings.

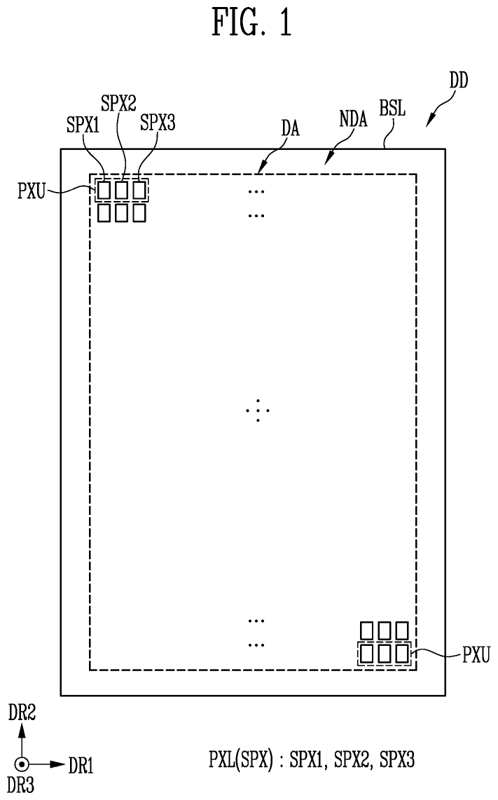

FIG. 1 is a schematic plan view illustrating a display device according to one or more embodiments.

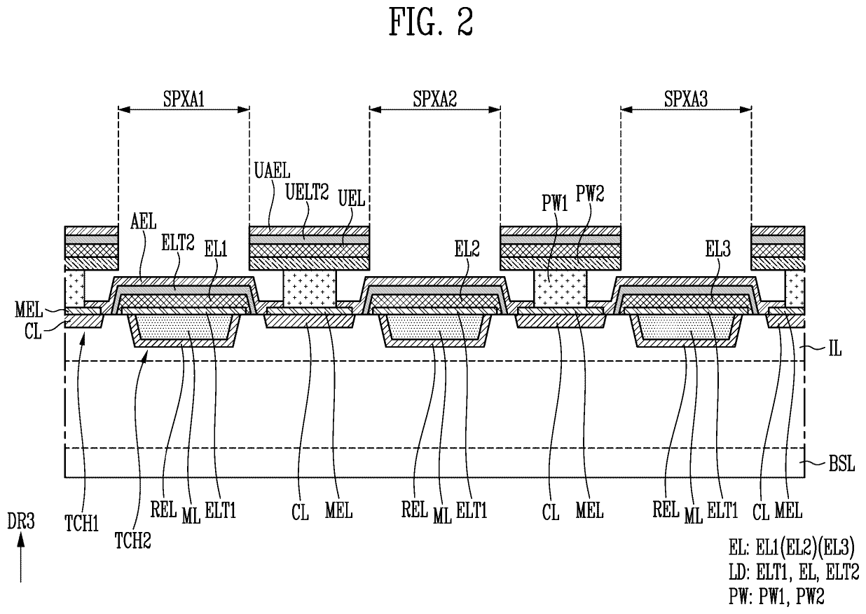

Referring to FIG. 1, a display device DD may be configured to emit light. The display device DD may include a light-emitting element LD (see FIG. 2). According to one or more embodiments, the display device DD may be a device that displays a moving image or a still image. The display device DD may be used as display screens for various products, such as television, a laptop, a monitor, a billboard, and an Internet of Things (IOT), as well as portable electronic devices, such as a mobile phone, a smart phone, a tablet personal computer, a smart watch, a watch phone, a mobile communication terminal, an electronic notebook, an e-book, a portable multimedia player (PMP), a navigation, and an UMPC (Ultra Mobile PC). However, the application field of the display device DD is not limited to any particular example.

The display device DD may be formed in the form of a rectangular flat plate having a short side in a first direction DR1 and a long side in a second direction DR2 that intersects the first direction DR1. A corner portion where the short side in the first direction DR1 and the long side in the second direction DR2 meet may be rounded to have a curvature (e.g., predetermined curvature), or may be formed at a right angle. The planar shape of the display device DD is not limited to a rectangular shape, but may be formed in another polygonal shape or a round shape, such as a circle or oval. The display device DD may be formed flat, but the disclosure is not limited thereto. For example, the display device DD may include a curved portion formed at left and right ends, and having a constant curvature or a changing curvature. In addition, the display device DD may be flexible so that it can be curved, bent, folded, or rolled.

In the disclosure, the first direction DR1 may be a row direction of a pixel PXL and may be a horizontal direction. The second direction DR2 may be a column direction of the pixel PXL. A third direction DR3 may be a display direction of the display device DD or a normal direction of a plane where a base layer BSL is located. In addition, in the disclosure, an upper direction may be the third direction DR3, and a lower direction may be a direction opposite to the third direction DR3 and may be a direction of gravity.

The display device DD may include a display area DA and a non-display area NDA. The non-display area NDA may refer to an area excluding the display area DA. The non-display area NDA may surround at least a portion of the display area DA.

The display area DA may refer to an area where the pixel PXL is located. The non-display area NDA may refer to an area where no pixel PXL is located. A driving circuit unit, wirings, and pads connected to the pixel PXL of the display area DA may be located in the non-display area NDA.

According to one or more embodiments, the pixel PXL (or sub-pixels SPX) may include a first sub-pixel SPX1, a second sub-pixel SPX2, and a third sub-pixel SPX3. At least one first sub-pixel SPX1, second sub-pixel SPX2, and third sub-pixel SPX3 may form one pixel unit PXU capable of emitting light of various colors. FIG. 1 shows an example where each pixel PXL includes three sub-pixels SPX1, SPX2, SPX3, that is, the first sub-pixel SPX1, the second sub-pixel SPX2, and the third sub-pixel SPX3, but embodiments of the disclosure are not limited thereto.

According to one or more embodiments, the pixel PXL (or sub-pixels SPX) may be arranged in a structure, such as a stripe, PENTILE™, or the like (PENTILE™ being a registered trademark of Samsung Display Co., Ltd., Republic of Korea). However, the disclosure is not necessarily limited thereto.

The first sub-pixel SPX1 may emit first light, the second sub-pixel SPX2 may emit second light, and the third sub-pixel SPX3 may emit third light. Here, the first light may be light in a red wavelength band, the second light may be light in a green wavelength band, and the third light may be light in a blue wavelength band. The red wavelength band may be a wavelength band of about 600 nm to about 750 nm, the green wavelength band may be a wavelength band of about 480 nm to about 560 nm, and the blue wavelength band may be a wavelength band of about 370 nm to about 460 nm, but embodiments of the disclosure are not limited thereto.

Each of the first sub-pixel SPX1, the second sub-pixel SPX2, and the third sub-pixel SPX3 may include an organic light-emitting element (OLED) that emits light.

Hereinafter, the display device DD including an organic light-emitting element according to embodiments will be described with reference to FIGS. 2 to 5.

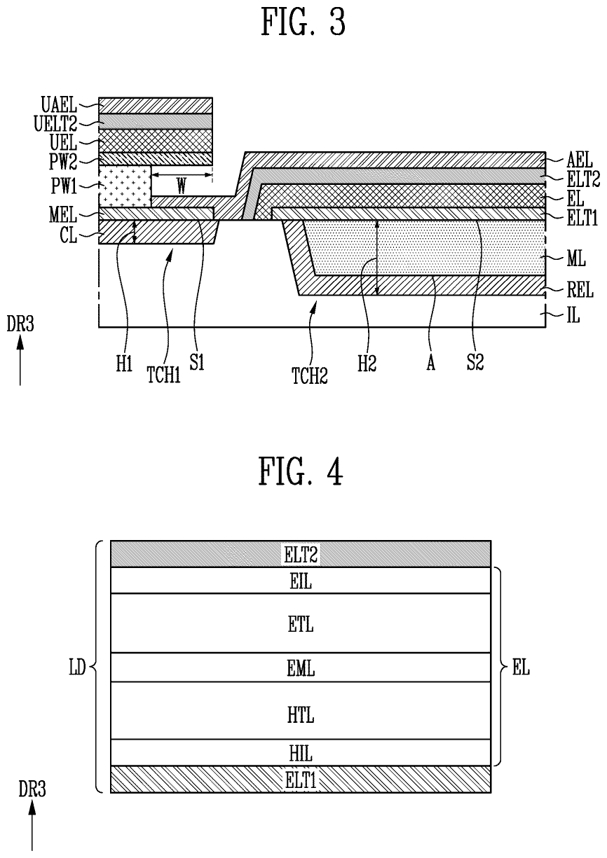

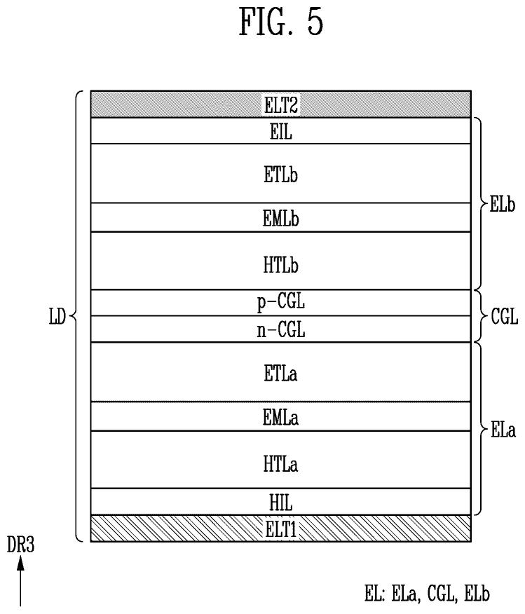

FIG. 2 is a schematic cross-sectional view illustrating the display device according to one or more embodiments. FIG. 3 is a schematic cross-sectional view enlarging an area of FIG. 2. FIG. 3 may be an enlarged view of a partition wall PW and the light-emitting element LD of FIG. 2. FIG. 4 is a cross-sectional view illustrating one or more embodiments of a light-emitting element of FIG. 2. FIG. 5 is a cross-sectional view illustrating one or more other embodiments of the light-emitting element of FIG. 2.

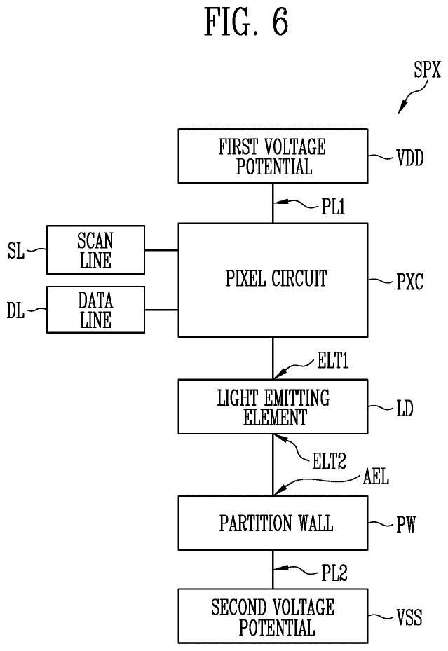

Referring to FIGS. 2 and 3, the display device DD may include a base layer BSL and an insulating layer IL located on the base layer BSL (as used herein, “located on” or “on” may mean “above”). Conductive layers for forming pixel circuits PXC (see FIG. 6), and insulating layers located between the conductive layers, may be located between the base layer BSL and the insulating layer IL.

According to one or more embodiments, a pixel circuit PXC may include circuit elements (for example, a driving transistor and the like), and may be electrically connected to light-emitting elements LD to provide an electrical signal so that the light-emitting elements LD emit light.

According to one or more embodiments, the display device DD may include a reflective electrode REL, an intermediate layer ML, the partition wall PW, and the light-emitting element LD located on the insulating layer IL.

The insulating layer IL may include a first trench TCH1 and a second trench TCH2. The first trench TCH1 and the second trench TCH2 may refer to grooves formed in, or defined by, the insulating layer IL. The first trench TCH1 and the second trench TCH2 may form step differences on a surface (for example, an upper surface) of the insulating layer IL.

According to one or more embodiments, the first trench TCH1 and the second trench TCH2 may have different heights. For example, the first trench TCH1 may have a first trench height H1. The second trench TCH2 may have a second trench height H2. The second trench height H2 may be higher than the first trench height H1. According to one or more embodiments, a difference between the second trench height H2 and the first trench height H1 may be about 500 Å to about 1000 Å.

The insulating layer IL may include an organic material or an inorganic material. For example, the organic material may include one or more selected from the group consisting of an acryl resin, an epoxy resin, a phenol resin, a polyamide resin, a polyimide resin, a polyester resin, a polyphenylenesulfide resin, or benzocyclobutene. For example, the inorganic material may include one or more selected from the group consisting of silicon nitride (SiNx), aluminum nitride (AlNx), titanium nitride (TiNx), silicon oxide (SiOx), aluminum oxide (AlxOy), titanium oxide (TiOx), silicon oxycarbide (SiOxCy), or silicon oxynitride (SiOxNy). However, the disclosure is not limited thereto.

The reflective electrode REL may be located in the second trench TCH2. For example, at least a portion of the reflective electrode REL may be located in the second trench TCH2. The reflective electrode REL may contact at least a portion of the insulating layer IL.

The reflective electrode REL may be a reflective layer. The reflective electrode REL may include a reflective surface A. According to one or more embodiments, the reflective electrode REL may include a bent portion. For example, the reflective surface A may include an inclined surface (for example, a tapered side surface), and may include a surface (for example, a base surface) that is substantially parallel to a plane at which the base layer BSL is located.

The reflective electrode REL may include a metal having reflective properties. For example, the reflective electrode REL may include silver (Ag). Silver (Ag) has a relatively higher light reflectance than other metals. Therefore, when the reflective electrode REL includes silver (Ag), light emitted from the light-emitting element LD can be effectively guided toward the front of the display device DD. However, the disclosure is not limited thereto, and the reflective electrode REL may include various types of metals known as metals having reflective properties.

The intermediate layer ML may be located on the reflective electrode REL. The intermediate layer ML may be a layer located between the reflective electrode REL and the light-emitting element LD. The intermediate layer ML may contact at least a portion of the reflective electrode REL. For example, a lower surface of the intermediate layer ML may contact the reflective surface A. At least a portion of the intermediate layer ML may be surrounded by at least a portion of the reflective electrode REL. For example, a side surface of the intermediate layer ML may be surrounded by a side surface (for example, the tapered side surface) of the reflective surface A.

The intermediate layer ML may include an intermediate layer upper surface S2 that is substantially parallel to the plane at which the base layer BSL is located. The intermediate layer upper surface S2 may be substantially flat. The intermediate layer upper surface S2 may be at the same plane as at least a portion of an upper surface of the insulating layer IL. The intermediate layer upper surface S2 may be at the same plane as at least a portion of one surface of the reflective electrode REL (e.g., an edge of the reflective electrode REL).

The intermediate layer ML may be an insulating layer. The intermediate layer ML may include one or more of silicon oxide (SiOx) or silicon nitride (SiNx). According to one or more embodiments, the intermediate layer ML may include silica (SiO₂). However, the disclosure is not limited thereto, and the intermediate layer ML may include various types of materials known as insulating materials.

The light-emitting element LD may be located on the insulating layer IL (or the base layer BSL). According to one or more embodiments, the light-emitting element LD may include a first electrode ELT1, a light-emitting unit EL, and a second electrode ELT2.

First electrodes ELT1 may be located on the base layer BSL. Portions of the first electrodes ELT1 may contact the intermediate layer ML and at least portion of the reflective electrode REL. Portions of the first electrodes ELT1 may overlap the intermediate layer ML and at least a portion of the reflective electrode REL in a plan view.

Light emitting units EL may be located on the first electrodes ELT1. The light-emitting units EL may cover the first electrodes ELT1. The light-emitting unit EL may entirely overlap the first electrode ELT1 in a plan view.

Second electrodes ELT2 may be located on the light-emitting units EL. The second electrodes ELT2 may cover the light-emitting units EL. The second electrodes ELT2 may entirely overlap the light-emitting units EL in a plan view.

According to one or more embodiments, the light-emitting units EL may be located in areas (for example, a first sub-pixel area SPXA1, a second sub-pixel area SPXA2, and a third sub-pixel area SPXA3 in FIG. 2) defined by partition walls PW. Each of the light-emitting units EL may be located between the partition walls PW. The light-emitting unit EL may be located adjacent to the partition wall PW. The light-emitting unit EL may include a first light-emitting unit EL1 for forming the first sub-pixel SPX1 emitting light of a first color, a second light-emitting unit EL2 for forming the second sub-pixel SPX2 emitting light of a second color, and a third light-emitting unit EL3 for forming the third sub-pixel SPX3 emitting light of a third color.

One surface of the light-emitting unit EL may be electrically connected to one surface of the first electrode ELT1, and the other surface of the light-emitting unit EL may be electrically connected to the second electrode ELT2.

The first electrode ELT1 may be an anode electrode for the light-emitting unit EL, and the second electrode ELT2 may be a cathode electrode for the light-emitting unit EL. According to one or more embodiments, the first electrode ELT1 and the second electrode ELT2 may include a conductive material. For example, the first electrode ELT1 may include a conductive material having reflective properties, and the second electrode ELT2 may include a transparent conductive material. For example, the first electrode ELT1 may include indium tin oxide (ITO). The disclosure is not necessarily limited thereto. The first electrode ELT1 may be a cathode electrode for the light-emitting unit EL, and the second electrode ELT2 may be an anode electrode for the light-emitting unit EL.

Referring to FIG. 4, the light-emitting unit EL may have a multilayer thin film structure including a light generation layer (for example, a light-emitting layer EML). The light-emitting unit EL may include a hole injection layer HIL that injects holes, a hole transport layer HTL that has excellent hole transport properties and that suppresses the movement of electrons that are not combined in the light-emitting layer EML to increase the chance of recombination of holes and electrons, the light-emitting layer EML that emits light by recombination of injected electrons and holes, an electron transport layer ETL to smoothly transport electrons to the light-emitting layer, and an electron injection layer EIL that injects electrons. The light-emitting unit EL may emit light based on an electrical signal provided from the anode electrode (for example, the first electrode ELT1) and the cathode electrode (for example, the second electrode ELT2).

According to one or more embodiments, referring to FIG. 5, the light-emitting element LD may include a tandem structure. For example, the light-emitting unit EL may further include a first light-emitting unit ELa, a charge generation layer CGL, and a second light-emitting unit ELb.

The first light-emitting unit ELa may have a structure in which a hole injection layer HIL, a first hole transport layer HTLa, a first light-emitting layer EMLa, and a first electron transport layer ETLa are stacked in the third direction DR3. The second light-emitting unit ELb may have a structure in which a second hole transport layer HTLb, a second light-emitting layer EMLb, a second electron transport layer ETLb, and an electron injection layer EIL are stacked in the third direction DR3.

In one or more embodiments, a buffer layer may be located on the first light-emitting layer EMLa and the second light-emitting layer EMLb. The buffer layer may include an electron transport compound.

The charge generation layer CGL may supply charges to the first light-emitting unit ELa and the second light-emitting unit ELb. The charge generation layer CGL may include an n-type charge generation layer n-CGL for supplying charges to the first light-emitting unit ELa and a p-type charge generation layer p-CGL for supplying holes to the second light-emitting unit ELb. In this case, the n-type charge generation layer n-CGL may include a metal material as a dopant.

FIG. 5 shows an example in which two light-emitting units ELa and ELb are stacked within the light-emitting element LD, but the disclosure is not limited thereto. For example, three or four or more light-emitting units may be stacked within the light-emitting element LD.

Referring back to FIG. 3, according to one or more embodiments, the display device DD may further include a connection electrode CL, an intermediate electrode MEL, and an auxiliary electrode AEL.

The connection electrode CL may be located in the first trench TCH1. For example, at least a portion of the connection electrode CL may be located in the first trench TCH1. The connection electrode CL may contact at least a portion of the insulating layer IL.

The connection electrode CL may include a connection electrode upper surface S1, which is a surface (for example, a base surface) substantially parallel to the plane at which the base layer BSL is located. The connection electrode upper surface S1 may be substantially flat. The connection electrode upper surface S1 may be at the same plane as at least a portion of the upper surface of the insulating layer IL. The connection electrode upper surface S1 may be at the same plane as the intermediate layer upper surface S2. The connection electrode upper surface S1 may be at the same plane as at least a portion of one surface of the reflective electrode REL.

The connection electrode CL may be a layer formed in the same deposition process as the reflective electrode REL, and may refer to a layer including the same material. For example, the connection electrode CL may include silver (Ag).

The intermediate electrode MEL may be located on, and may contact, the connection electrode CL. The intermediate electrode MEL may overlap at least a portion of the connection electrode CL in a plan view. The intermediate electrode MEL may not overlap the light-emitting element LD in a plan view.

The intermediate electrode MEL may be a layer formed in a same deposition process as the first electrode ELT1, and may refer to a layer including a same material. For example, the intermediate electrode MEL may include a conductive material having reflective properties. For example, the intermediate electrode MEL may include indium tin oxide (ITO).

The intermediate electrode MEL may have the same thickness as the first electrode ELT1. For example, the thickness of the intermediate electrode MEL and the first electrode ELT1 may be about 50 Å to about 200 Å.

According to one or more embodiments, the intermediate electrode MEL may be removed by patterning during a manufacturing process of the display device DD. In this case, the display device DD may not include the intermediate electrode MEL. This will be described later with reference to FIG. 11.

The partition wall PW may be located on the intermediate electrode MEL (or the connection electrode CL). Each of the partition walls PW may be located between the light-emitting units EL. The partition walls PW may be located between or at boundaries of adjacent sub-pixels SPX1, SPX2, and SPX3 to define the first sub-pixel area SPXA1, the second sub-pixel area SPXA2, and the third sub-pixel area SPXA3.

The partition wall PW may include a multi-layer laminated structure. According to one or more embodiments, the partition wall PW may include a double layer structure. For example, the partition wall PW may include a first partition wall layer PW1 and a second partition wall layer PW2. However, the disclosure is not necessarily limited thereto. Hereinafter, a case where the partition wall PW has a double layer structure including a first partition wall layer PW1 and a second partition wall layer PW2 will be described as an example.

The first partition wall layer PW1 and the second partition wall layer PW2 may be stacked in a thickness direction (for example, the third direction DR3) of the base layer BSL. For example, the first partition wall layer PW1 may be located on the connection electrode CL. The second partition wall layer PW2 may be located on the first partition wall layer PW1.

The first partition wall layer PW1 may have a narrower width than the second partition wall layer PW2. For example, the second partition wall layer PW2 may protrude outwardly further than the first partition wall layer PW1 in the first direction DR1 or the second direction DR2. For example, the second partition wall layer PW2 may protrude outwardly further than the first partition wall layer PW1 by a protruding length w. The protruding length w may be about 0.3 μm to about 1 μm.

According to one or more embodiments, the partition wall PW may have a T-shaped structure. For example, the partition wall PW may form a tip structure in which the first partition wall layer PW1 is recessed inwardly further than the second partition wall layer PW2.

The partition wall PW may have a tip structure, and when depositing organic materials for forming the light-emitting units EL, the light-emitting units EL may be separated from each other, and the sub-pixels SPX1, SPX2, and SPX3 may be distinguished from each other. For example, the light-emitting unit EL may be divided into the first light-emitting unit EL1, the second light-emitting unit EL2, and the third light-emitting unit EL3. The light-emitting unit EL may not cover at least a portion of the side surface of the first partition wall layer PW1. The light-emitting units EL may not contact the first partition wall layer PW1. Accordingly, the risk of leakage current flowing between the light-emitting units EL and the partition walls PW can be reduced.

The partition wall PW may have a tip structure, and when depositing materials for forming the second electrode ELT2, the second electrodes ELT2 may be separated from each other. The second electrode ELT2 may be spaced apart (or separated) from the partition wall PW. For example, the second electrode ELT2 may not cover at least a portion of the side surface of the first partition wall layer PW1. The second electrode ELT2 may not contact the first partition wall layer PW1.

The first partition wall layer PW1 may have a same thickness as the second partition wall layer PW2, or may have a greater thickness than the second partition wall layer PW2. For example, the first partition wall layer PW1 may have a thickness of about 1000 Å to about 2000 Å. The second partition wall layer PW2 may have a thickness of about 1000 Å to about 3000 Å.

In the disclosure, the width may be defined based on an extension direction in which the plane in which the base layer BSL is located (for example, the first direction DR1 or the second direction DR2), and the thickness may be defined based on the thickness direction (for example, the third direction DR3) of the base layer BSL.

The partition wall PW may include a metal material. For example, the metal material may include one or more selected from the group consisting of gold (Au), silver (Ag), aluminum (Al), molybdenum (Mo), chromium (Cr), titanium (Ti), nickel (Ni), neodymium (Nd), copper (Cu), or platinum (Pt).

According to one or more embodiments, the first partition wall layer PW1 may include aluminum (Al). According to one or more embodiments, the second partition wall layer PW2 may include titanium (Ti). However, the disclosure is not limited thereto.

The auxiliary electrode AEL may be located on the second electrode ELT2. The auxiliary electrode AEL may be located on the second electrode ELT2 and the intermediate electrode MEL (or the connection electrode CL). The auxiliary electrode AEL may entirely cover the second electrode ELT2. The auxiliary electrode AEL may overlap the second electrode ELT2 and at least a portion of the intermediate electrode MEL (or the connection electrode CL) in a plan view. According to one or more embodiments, the auxiliary electrode AEL may contact the side surface of the first partition wall layer PW1. However, the disclosure is not limited thereto. According to one or more embodiments, the auxiliary electrode AEL may not contact the side surface of the first partition wall layer PW1.

The auxiliary electrode AEL may have a thickness of about 100 Å to about 1000 Å. The auxiliary electrode AEL may be a transparent conductive layer. The auxiliary electrode AEL may include a transparent metal material. According to one or more embodiments, the auxiliary electrode AEL may include Transparent Conductive Oxide (TCO) material. For example, the TCO material may be one or more selected from the group consisting of Indium Tin Oxide (ITO), Indium Zinc Oxide (IZO), Indium Gallium Zinc Oxide (IGZO), Aluminum Zinc Oxide (AZO), or Titanium Nitride (TiN).

The auxiliary electrode AEL may electrically connect the second electrode ELT2 and the partition wall PW. For example, the auxiliary electrode AEL may be electrically connected to the connection electrode CL located below the partition wall PW, and the connection electrode CL may be electrically connected to the partition wall PW. The auxiliary electrode AEL may electrically connect the second electrode ELT2 and the partition wall PW through the connection electrode CL. Accordingly, the auxiliary electrode AEL may prevent the second electrode ELT2 from being disconnected by the partition wall PW. For example, the auxiliary electrode AEL may electrically connect the second electrode ELT2, which is separated from the partition wall PW, to the partition wall PW.

In the display device DD according to the disclosure, the auxiliary electrode AEL may be electrically connected to the connection electrode CL including the flat connection electrode upper surface S1. Accordingly, the second electrode ELT2 may be stably electrically connected to the partition wall PW.

According to one or more embodiments, the display device DD may further include an upper light-emitting unit UEL, an upper second electrode UELT2, and an upper auxiliary electrode UAEL.

The upper light-emitting unit UEL may be located on the partition wall PW. In the disclosure, the upper light-emitting unit UEL may refer to a layer formed in the same deposition process as the light-emitting unit EL that emits light. The upper light-emitting unit UEL may be located on the second partition wall layer PW2. The upper light-emitting unit UEL may overlap at least a portion of the second partition wall layer PW2 in a plan view. The upper light-emitting unit UEL may contact at least a portion of the second partition wall layer PW2. The upper light-emitting unit UEL may cover at least a portion of the second partition wall layer PW2. In this drawing, the upper light-emitting unit UEL entirely covers the second partition wall layer PW2, but the disclosure is not limited thereto. For example, the upper light-emitting unit UEL may expose at least a portion of the second partition wall layer PW2.

The upper second electrode UELT2 may be located on the upper light-emitting unit UEL. In the disclosure, the upper second electrode UELT2 may refer to a layer formed in a same deposition process as the second electrode ELT2 that is located between the partition walls PW. The upper second electrode UELT2 may overlap at least a portion of the second partition wall layer PW2 in a plan view. The upper second electrode UELT2 may overlap at least a portion of the upper light-emitting unit UEL in a plan view. In this drawing, the upper second electrode UELT2 entirely covers the second partition wall layer PW2, but the disclosure is not limited thereto. The upper second electrode UELT2 may expose at least a portion of the second partition wall layer PW2.

The upper auxiliary electrode UAEL may be located on the upper second electrode UELT2. In the disclosure, the upper auxiliary electrode UAEL may refer to a layer formed in a same deposition process as the auxiliary electrode AEL located between the partition walls PW. The upper auxiliary electrode UAEL may overlap at least a portion of the second partition wall layer PW2 in a plan view. The upper auxiliary electrode UAEL may overlap the upper second electrode UELT2 and at least a portion of the upper light-emitting unit UEL in a plan view. In this drawing, the upper auxiliary electrode UAEL entirely covers the second partition wall layer PW2, but the disclosure is not limited thereto. The upper auxiliary electrode UAEL may expose at least a portion of the second partition wall layer PW2.

Hereinafter, an electrical connection structure for the light-emitting element will be described with reference to FIGS. 2 and 6. FIG. 6 is a schematic block diagram illustrating an electrical connection structure for the light-emitting element according to one or more embodiments. For example, FIG. 6 may show an electrical connection structure including the pixel circuit PXC corresponding to each sub-pixel SPX.

Referring to FIGS. 2 and 6, the sub-pixel SPX may include the pixel circuit PXC configured to drive the light-emitting element LD.

The pixel circuit PXC may include one or more circuit elements. For example, the pixel circuit PXC may include transistors and a storage capacitor. For example, the pixel circuit PXC may include a driving transistor, a switching transistor, and a storage capacitor. However, the disclosure is not necessarily limited thereto.

The pixel circuit PXC may be electrically connected to a scan line SL and a data line DL. The scan line SL may supply a scan signal to the pixel circuit PXC. According to one or more embodiments, the scan line SL may be electrically connected to a gate electrode of the switching transistor of the pixel circuit PXC. The light-emitting element LD may be configured to emit light corresponding to a data signal provided from the data line DL.

The pixel circuit PXC may be electrically connected to a first power source line PL1 and a second power source line PL2. For example, the first electrode ELT1 of the light-emitting element LD may be electrically connected to the pixel circuit PXC and the first power source line PL1. The second electrode ELT2 of the light-emitting element LD may be electrically connected to the second power source line PL2. According to one or more embodiments, the second power source line PL2 may be formed on the base layer BSL within the display area DA. Alternatively, in one or more other embodiments, the second power source line PL2 may be located within the non-display area NDA. Accordingly, the second power source line PL2 may be configured to supply a second power source to the light-emitting element LD.

A power source of the first power source line PL1 and a power source of the second power source line PL2 may have different potentials. For example, the power source of the first power source line PL1 may be a high-potential pixel power source supplied from a first voltage potential VDD. The power source of the second power source line PL2 may be a low-potential pixel power source supplied from a second voltage potential VSS. A potential difference between the power source of the first power source line PL1 and the power source of the second power source line PL2 may be set to be higher than a threshold voltage of the light-emitting elements LD.

The first power source line PL1 may be electrically connected to the pixel circuit PXC (for example, the driving transistor). The second power source line PL2 may be electrically connected to the cathode electrode (for example, the second electrode ELT2) of the light-emitting element LD.

In one or more embodiments, the second power source line PL2 may be electrically connected to the second electrode ELT2 through the partition wall PW and the auxiliary electrode AEL. For example, the partition wall PW and the auxiliary electrode AEL may electrically connect the second electrode ELT2 and the second power source line PL2.

Each light-emitting element LD may be connected in a forward direction between the first power source line PL1 and the second power source line PL2 to form each effective light source. These effective light sources can be gathered together to form the light-emitting elements LD of the sub-pixels SPX.

The light-emitting elements LD may emit light with a luminance corresponding to a driving current supplied through the pixel circuit PXC. During each frame period, the pixel circuit PXC may supply the driving current corresponding to the data signal to the light-emitting element LD. The light-emitting element LD may emit light with a luminance corresponding to a current flowing through it.

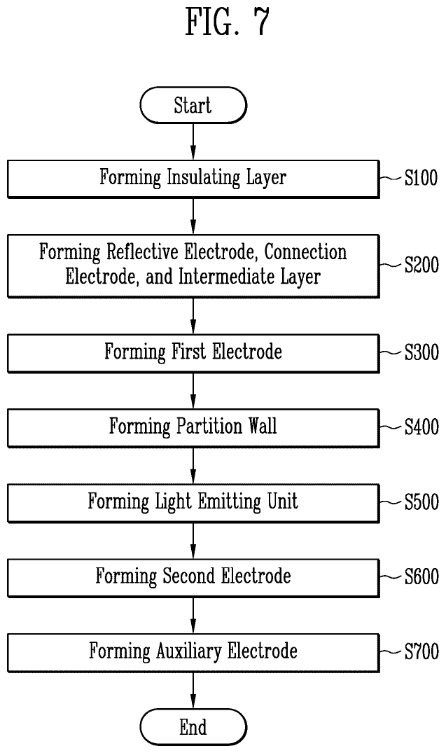

Hereinafter, a method of manufacturing a display device DD will be described with reference to FIGS. 7 to 14.

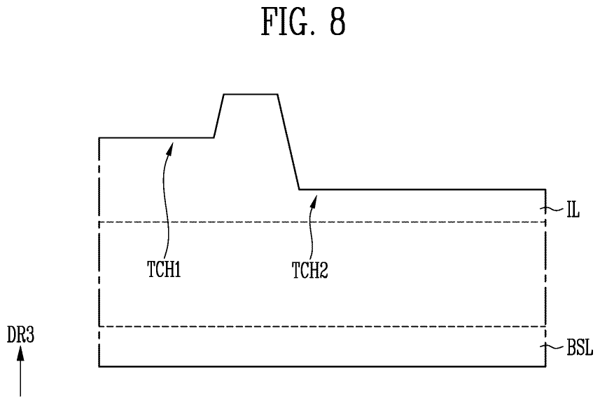

FIG. 7 is a flowchart illustrating a method of manufacturing a display device according to one or more embodiments. FIGS. 8 to 14 are schematic cross-sectional views illustrating the method of manufacturing the display device according to one or more embodiments.

Referring to FIG. 7, the method of manufacturing the display device DD may include forming an insulating layer (S100), forming a reflective electrode, a connection electrode, and an intermediate layer (S200), forming a first electrode (S300), forming a partition wall (S400), forming a light-emitting unit (S500), forming a second electrode (S600), and forming an auxiliary electrode (S700).

Referring to FIG. 8, before the forming the insulating layer (S100), conductive layers constituting a pixel circuit PXC for driving light-emitting elements LD, and insulating layers located between the conductive layers, may be formed on a base layer BSL.

According to one or more embodiments, components located on the base layer BSL may be formed through conventional patterning processes (for example, a photolithography process and the like) using masks.

The forming the insulating layer (S100) may include forming an insulating layer IL on the conductive layers (or the base layer BSL) constituting the pixel circuit PXC.

In the forming the insulating layer (S100), a base insulating layer for forming the insulating layer IL may be deposited and then etched to form an inclined surface (for example, a tapered side surface). The insulating layer IL may have step differences. The base insulating layer may be deposited on the base layer BSL, and then may be etched to form a first trench TCH1 and a second trench TCH2 having different heights.

According to one or more embodiments, a photoresist having different respective thicknesses in different areas may be located on the base insulating layer. The base insulating layer overlapping the photoresist having different thicknesses in a plan view may be etched at different thicknesses to form the first trench TCH1 and the second trench TCH2.

For example, the base insulating layer may be etched so that the second trench TCH2 has a deeper structure than the first trench TCH1. For example, the base insulating layer may be etched so that the second trench TCH2 has a higher height than the first trench TCH1.

In the disclosure, as processes for depositing components of the display device DD, one or more of a chemical vapor deposition (CVD) process or an atomic layer deposition (ALD) process may be used. In the disclosure, as an etching process, one or more of a wet etching process or a dry etching process may be used. However, the disclosure is not limited to specific examples.

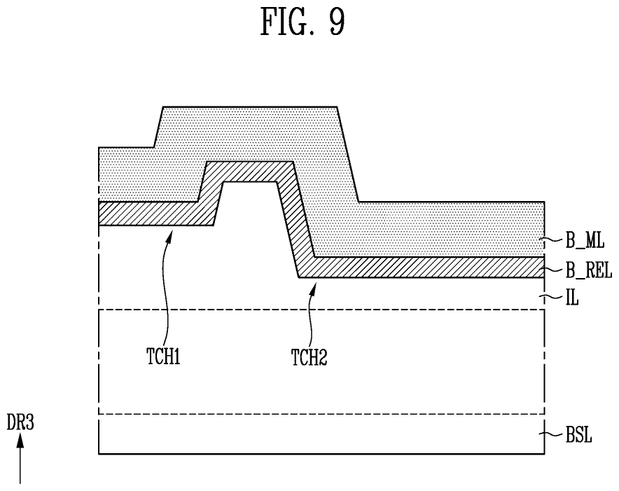

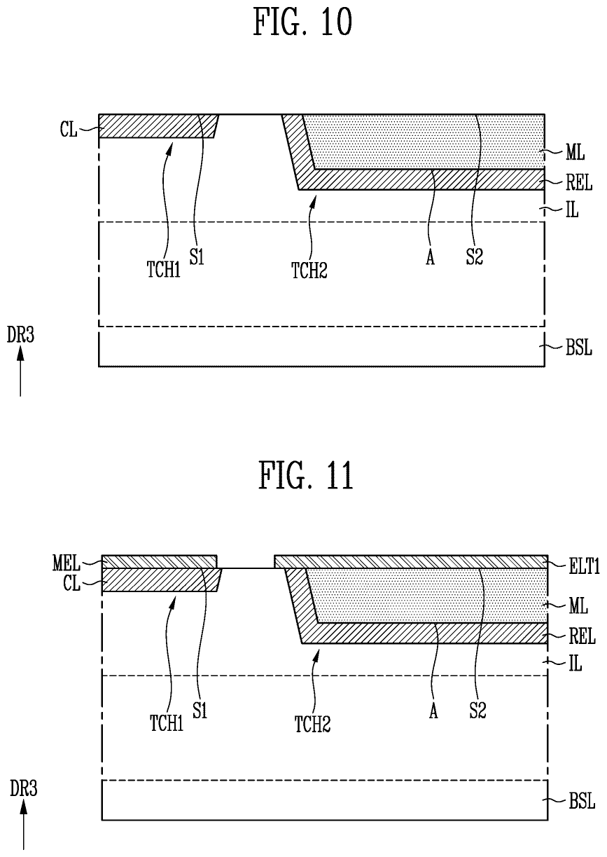

Referring to FIGS. 9 and 10, in the forming the reflective electrode, the connection electrode, and the intermediate layer (S200), a reflective electrode REL, a connection electrode CL, and an intermediate layer ML may be formed on the insulating layer IL.

The forming the reflective electrode, the connection electrode, and the intermediate layer (S200) may include depositing a base reflective electrode B_REL and depositing a base intermediate layer B_ML.

In the depositing the base reflective electrode B_REL, the base reflective electrode B_REL may be deposited on the insulating layer IL. According to one or more embodiments, the base reflective electrode B_REL may be deposited directly on the insulating layer IL. The base reflective electrode B_REL may be deposited on the inclined surface of the insulating layer IL, and the base reflective electrode B_REL may include an inclined surface (for example, a tapered side surface).

The base reflective electrode B_REL may include a material including a metal having reflective properties. For example, the base reflective electrode B_REL may include silver (Ag).

In the depositing the base intermediate layer B_ML, the base intermediate layer B_ML may be deposited on the base reflective electrode B_REL. According to one or more embodiments, the base intermediate layer B_ML may be deposited directly on the base reflective electrode B_REL. The base intermediate layer B_ML may be deposited on the inclined surface of the base reflective electrode B_REL, and the base intermediate layer B_ML may include an inclined surface.

The base intermediate layer B_ML may include an insulating material. For example, the base intermediate layer B_ML may include one or more of silicon oxide (SiOx) or silicon nitride (SiNx).

The forming the reflective electrode, the connection electrode, and the intermediate layer S200 may include polishing the base reflective electrode B_REL and the base intermediate layer B_ML.

In the polishing of the base reflective electrode B_REL and the base intermediate layer B_ML, at least a portion of the base reflective electrode B_REL and at least a portion of the base intermediate layer B_ML may be polished. In addition, in the polishing of the base reflective electrode B_REL and the base intermediate layer B_ML, at least a portion of the insulating layer IL may be further polished. The process of polishing the base reflective electrode B_REL, the base intermediate layer B_ML, and the insulating layer IL may be a chemical mechanical polishing (CMP) process.

At least a portion of the insulating layer IL may be polished so that the first trench TCH1 and the second trench TCH2 have a height difference of about 500 Å to about 1000 Å.

The base reflective electrode B_REL may be polished to separate at least a portion of the base reflective electrode B_REL, and to expose the insulating layer IL. The base reflective electrode B_REL may be polished to form the connection electrode CL and the reflective electrode REL.

According to the method of manufacturing the display device DD according to the disclosure, the base reflective electrode B_REL may be polished through a CMP process to form the connection electrode CL and the reflective electrode REL at the same time, and a process for patterning the reflective electrode REL may not be performed separately. For example, experimentally, when the reflective electrode REL includes silver (Ag), it may be difficult to be dry etched. However, according to the method of manufacturing the display device DD according to the disclosure, the reflective electrode REL may not be separately dry etched. For example, the reflective electrode REL may be formed by performing only the polishing process after the deposition process. Accordingly, process steps can be simplified and the manufacturing cost of the display device DD can be reduced.

The base reflective electrode B_REL may be polished to form the connection electrode CL, at least a portion of which is located in the first trench TCH1 and includes a flat connection electrode upper surface S1. The connection electrode upper surface S1 may be at the same plane as at least a portion of an upper surface of the insulating layer IL.

The base reflective electrode B_REL may be polished to form the reflective electrode REL, at least a portion of which is located in the second trench TCH2 and includes an inclined reflective surface A. When the base reflective electrode B_REL is polished, the base intermediate layer B_ML may be located on the base reflective electrode B_REL, so that the reflective electrode REL can be protected.

The base intermediate layer B_ML may be polished so that the base intermediate layer B_ML located in the first trench TCH1 may be polished and the insulating layer IL may be exposed. The base intermediate layer B_ML may be polished to form the intermediate layer ML. The base intermediate layer B_ML may be polished to form the intermediate layer ML, at least a portion of which is located in the second trench TCH2 and includes a flat intermediate layer upper surface S2. As the base reflective electrode B_REL, the base intermediate layer B_ML, and the insulating layer IL are polished through the CMP process, the intermediate layer upper surface S2 may be at the same plane as at least a portion of the upper surface of the insulating layer IL and the connection electrode upper surface S1.

Referring to FIG. 11, in the forming the first electrode (S300), a first electrode ELT1 may be formed on the insulating layer IL (or the intermediate layer ML). According to one or more embodiments, a base first electrode for forming the first electrode ELT1 may be deposited on the insulating layer IL to cover the insulating layer IL. According to one or more embodiments, the base first electrode may be deposited to have a thickness of about 50 Å to about 200 Å, and may be etched to expose at least a portion of the insulating layer IL.

In the forming the first electrode (S300), at least a portion of the base first electrode may be etched, so that at least a portion of the base first electrode may be separated, and so that the first electrode ELT1 and the intermediate electrode MEL may be formed. For example, at least a portion of the base first electrode may be etched so that the intermediate electrode MEL may be formed in an area overlapping the connection electrode CL, and so that the first electrode ELT1 may be formed in an area overlapping the reflective electrode REL and the intermediate layer ML.

However, the disclosure is not limited thereto. According to one or more embodiments, at least a portion of the base first electrode may be further etched in the area overlapping the connection electrode CL, so that the intermediate electrode MEL may not be formed and the connection electrode CL may be exposed.

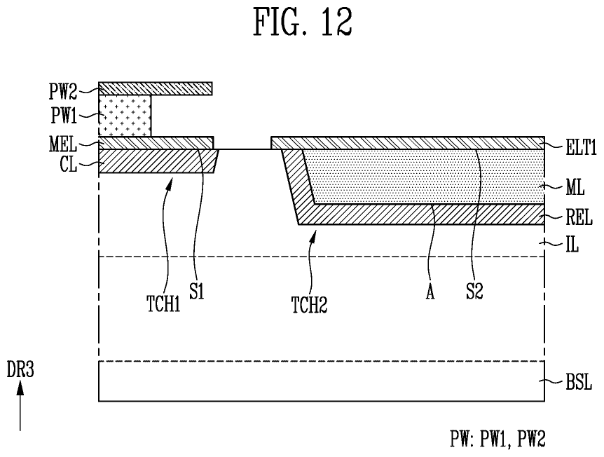

Referring to FIG. 12, in the forming the partition wall (S400), a partition wall PW may be formed on the connection electrode CL (or the intermediate electrode MEL). The partition wall PW may be deposited to have a multi-layer laminated structure. For example, based on the third direction DR3, a first base partition wall layer and a second base partition wall layer for forming a first partition wall layer PW1 and a second partition wall layer PW2 may be deposited on a pixel-defining layer PDL.

The first partition wall layer PW1 may include aluminum (Al). According to one or more embodiments, the second partition wall layer PW2 may include titanium (Ti). However, the disclosure is not limited thereto.

In the forming the partition wall (S300), after the first base partition wall layer and the second base partition wall layer are deposited, an etching process may be performed on the first base partition wall layer and the second base partition wall layer in consideration of the material of each layer.

The first partition wall layer PW1 may be formed to have the same thickness as the second partition wall layer PW2, or may be formed to have a thicker thickness than the second partition wall layer PW2. For example, the first partition wall layer PW1 may have a thickness of about 1000 Å to about 2000 Å. The second partition wall layer PW2 may have a thickness of about 1000 Å to about 3000 Å.

The first partition wall layer PW1 may be etched more, or relatively deeper, than the second partition wall layer PW2. For example, the first partition wall layer PW1 may be etched relatively deeper than the second partition wall layer PW2 so that the second partition wall layer PW2 protrudes outwardly further by a protruding length w than the first partition wall layer PW1. The protruding length w may be about 0.3 μm to about 1 μm. The second partition wall layer PW2 may be etched to protrude further towards an edge than the first partition wall layer PW1. The second partition wall layer PW2 may be etched to form a tip.

According to one or more embodiments, a cross section of the first partition wall layer PW1 may have a rectangular or square shape. However, the disclosure is not limited thereto. According to one or more embodiments, a side surface of the first partition wall layer PW1 may form an inclined surface. For example, the cross section of the first partition wall layer PW1 may have a trapezoidal shape that gradually narrows from the bottom to the top (for example, in the third direction DR3).

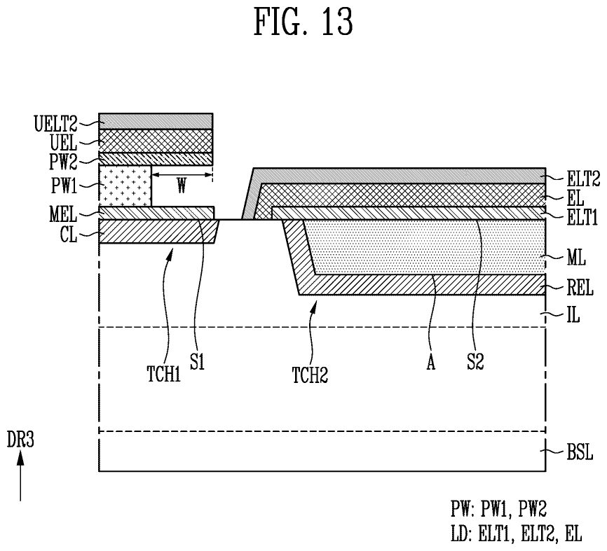

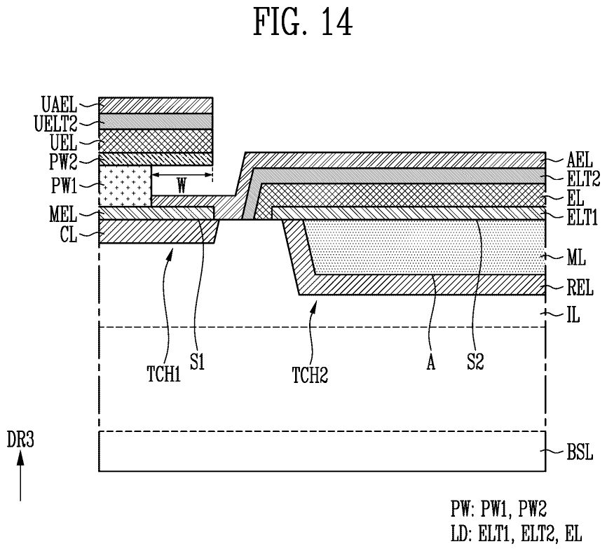

Referring to FIGS. 13 and 14, in the forming the light-emitting unit (S400), the light-emitting unit EL may be patterned (for example, deposited). The light-emitting unit EL may be deposited to be formed between partition walls PW. When the light-emitting unit EL is deposited, an upper light-emitting unit UEL may also be formed in the same deposition process. For example, the upper light-emitting unit UEL may be formed on the second partition wall layer PW2.

The light-emitting unit EL may be deposited on the first electrode ELT1 between the partition walls PW. The light-emitting unit EL may not contact a side surface of the partition wall PW. In the display device DD according to the disclosure, as the partition wall PW has the above-described structure, the light-emitting unit EL may not contact the side surface of the partition wall PW, and the risk of leakage current flowing between the light-emitting units EL and the partition walls PW can be reduced.

The upper light-emitting unit UEL may be deposited on the second partition wall layer PW2. The upper light-emitting unit UEL may cover at least a portion of the second partition wall layer PW2. According to one or more embodiments, the upper light-emitting unit UEL may entirely cover the second partition wall layer PW2. However, the disclosure is not limited thereto. The upper light-emitting unit UEL may expose at least a portion of the second partition wall layer PW2.

In the forming the second electrode (S600), a second electrode ELT2 may be deposited on the light-emitting unit EL. The second electrode ELT2 may be deposited to be formed between the partition walls PW. When the second electrode ELT2 is formed, an upper second electrode UELT2 may also be formed in the same deposition process.

The second electrode ELT2 may be deposited on the light-emitting unit EL between the partition walls PW. The light-emitting unit EL may not contact the side surface of the partition wall PW. In the display device DD according to the disclosure, as the partition wall PW has the above-described structure, the second electrode ELT2 may not contact the side surface of the partition wall PW.

The upper second electrode UELT2 may be deposited on the upper light-emitting unit UEL. The upper second electrode UELT2 may cover at least a portion of the upper light-emitting unit UEL. According to one or more embodiments, the upper second electrode UELT2 may entirely cover the second partition wall layer PW2. However, the disclosure is not limited thereto. The upper light-emitting unit UEL may expose at least a portion of the second partition wall layer PW2.

In the forming the auxiliary electrode (S700), an auxiliary electrode AEL may be formed on the second electrode ELT2. When the auxiliary electrode AEL is formed, an upper auxiliary electrode UAEL may also be formed in the same deposition process.

The auxiliary electrode AEL may be deposited to cover the second electrode ELT2 and at least a portion of the connection electrode CL (or the intermediate electrode MEL). The auxiliary electrode AEL may be directly located on the second electrode ELT2 and at least a portion of the insulating layer IL. According to one or more embodiments, the auxiliary electrode AEL may contact at least a portion of the side surface of the first partition wall layer PW1. The auxiliary electrode AEL may overlap at least a portion of the connection electrode CL (or the intermediate electrode MEL) in a plan view.

The auxiliary electrode AEL may be deposited to have a thickness of about 100 Å to about 1000 Å.

The upper auxiliary electrode UAEL may be deposited on the upper second electrode UELT2. The upper auxiliary electrode UAEL may cover at least a portion of the upper second electrode UELT2. According to one or more embodiments, the upper auxiliary electrode UAEL may entirely cover the second partition wall layer PW2. However, the disclosure is not limited thereto. The upper auxiliary electrode UAEL may expose at least a portion of the second partition wall layer PW2.

The auxiliary electrode AEL may include TCO material. For example, the TCO material may include one or more selected from the group consisting of Indium Tin Oxide (ITO), Indium Zinc Oxide (IZO), Indium Gallium Zinc Oxide (IGZO), Aluminum Zinc Oxide (AZO), or Titanium Nitride (TiN).

Because the auxiliary electrode AEL contacts the intermediate electrode MEL (or the connection electrode CL) and includes the TCO material, the auxiliary electrode AEL may electrically connect the partition wall PW and the second electrode ELT2. Accordingly, the auxiliary electrode AEL may prevent the second electrode ELT2 from being disconnected by the partition wall PW.

In addition, as the auxiliary electrode AEL is electrically connected to the connection electrode CL on the flat connection electrode upper surface S1, compared to the case where the auxiliary electrode AEL is electrically connected to the connection electrode CL on a substantially uneven surface, the second electrode ELT2 can be stably electrically connected to power source lines (for example, a second power source line PL2).

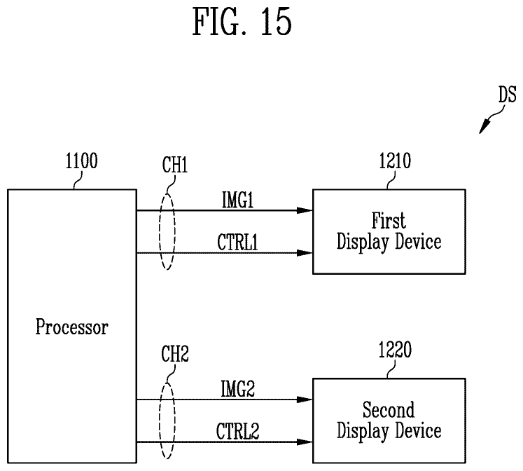

Hereinafter, a display system DS to which the display device DD can be applied will be described with reference to FIGS. 15 to 17.

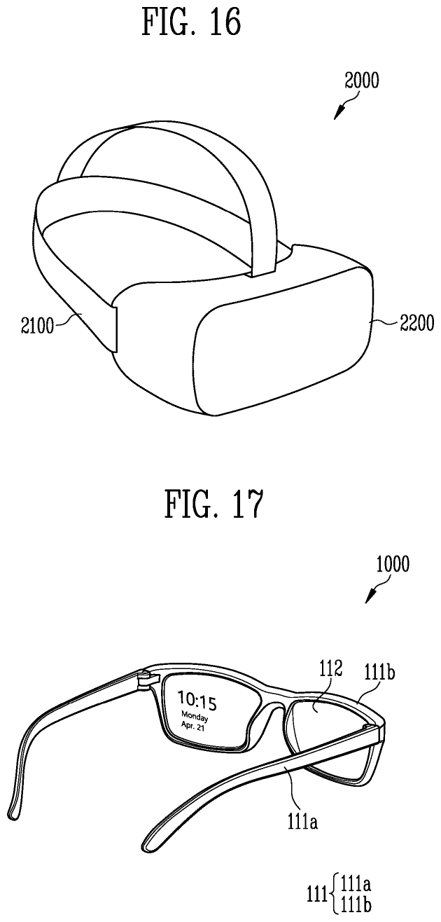

FIG. 15 is a block diagram schematically illustrating a display system according to one or more embodiments. FIGS. 16 and 17 are perspective views schematically illustrating an application example of the display system of FIG. 15.

Referring to FIG. 15, the display system DS may include a processor 1100 and one or more display devices 1210 and 1220.

The processor 1100 may perform various tasks and calculations. In some embodiments, the processor 1100 may include an application processor, a graphics processor, a microprocessor, a central processing unit (CPU), or the like. The processor 1100 may be connected to other components of the display system DS through a bus system and may control them.

FIG. 15 shows the display system DS including first and second display devices 1210 and 1220. The processor 1100 may be connected to the first display device 1210 through a first channel CH1, and may be connected to the second display device 1220 through a second channel CH2.

The processor 1100 may transmit first image data IMG1 and a first control signal CTRL1 to the first display device 1210 through the first channel CH1. The first display device 1210 may display an image based on the first image data IMG1 and the first control signal CTRL1. The first display device 1210 may be configured similarly to the display device DD described with reference to FIG. 1.

The processor 1100 may transmit second image data IMG2 and a second control signal CTRL2 to the second display device 1220 through the second channel CH2. The second display device 1220 may display an image based on the second image data IMG2 and the second control signal CTRL2. The second display device 1220 may be configured similarly to the display device DD described with reference to FIG. 1.

The display system DS may include a computing system that provides an image display function, such as a portable computer, a mobile phone, a smart phone, a tablet personal computer, a smart watch, a watch phone, a portable multimedia player (PMP), a navigation, and an ultra-mobile personal computer (UMPC). In addition, the display system DS may include at least one of a head-mounted display (HMD) device, a virtual reality (VR) device, a mixed reality (MR) device, and an augmented reality (AR) device.

Referring to FIG. 16, the display system DS of FIG. 15 may be applied to a head-mounted display device 2000. The head-mounted display device 2000 may be a wearable electronic device that can be worn on a user's head.

The head-mounted display device 2000 may include a head-mounting band 2100 and a display device storage case 2200. The head-mounting band 2100 may be connected to the display device storage case 2200. The head-mounting band 2100 may include a horizontal band and/or a vertical band for fixing the head-mounted display device 2000 to the user's head. The horizontal band may be configured to surround the sides of the user's head, and the vertical band may be configured to surround the top of the user's head. However, embodiments are not limited thereto. For example, the head-mounting band 2100 may be implemented in the form of glasses frames, helmets, or the like.

The display device storage case 2200 may accommodate the first and second display devices 1210 and 1220 of FIG. 15. The display device storage case 2200 may further accommodate the processor 1100 of FIG. 15.

Referring to FIG. 17, the display system DS of FIG. 15 may be applied to smart glasses 1000.

The smart glasses 1000 may include a frame 111 and a lens unit 112. The smart glasses 1000 may be a wearable electronic device that can be worn on a user's face, and may have a structure in which a portion of the frame 111 is folded or unfolded. For example, the smart glasses 1000 may be a wearable device for augmented reality. However, the disclosure is not limited thereto.

The frame 111 may include a housing 111b for supporting the lens unit 112, and a leg unit 111a to be worn by a user. The leg unit 111a may be connected to the housing 111b by a hinge, and may be folded or unfolded.

The frame 111 may be equipped with a battery, a touchpad, a microphone, a camera, etc. In addition, the frame 111 may be equipped with a projector that outputs light, a processor that controls optical signals or the like, etc.

The lens unit 112 may be an optical member that transmits or reflects light. The lens unit 112 may include glass, transparent synthetic resin, etc.

The display device DD may be applied to the lens unit 112 of the smart glasses 1000. As an example, a user may visually recognize an image displayed on the lens unit 112 by an optical signal transmitted from the projector of the frame 111. For example, the user may visually recognize information, such as time and date displayed on the lens unit 112.

A display device that can reduce the risk of leakage current occurring between partition walls, and a method of manufacturing the same, can be provided.

A display device in which the manufacturing process of the display device can be simplified, and a method of manufacturing the same, can be provided.

A display device in which a cathode electrode of a light-emitting element and a power source line can be stably electrically connected, and a method of manufacturing the same, can be provided.

As described above, embodiments of the disclosure have been disclosed through the detailed description and the drawings. However, those skilled in the art or those of ordinary skill in the art will appreciate that various modifications and changes are possible without departing from the spirit and technical scope of the disclosure as set forth in the claims below. Therefore, the technical protection scope of the disclosure is not limited to the detailed description described in the specification, but should be determined by the appended claims, with functional equivalents thereof to be included therein.

What is claimed is:

1. A display device comprising:
a base layer;
an insulating layer above the base layer, and defining a first trench and a second trench;
a connection electrode at least partially located in the first trench;
a reflective electrode at least partially located in the second trench;
an intermediate layer above the reflective electrode;
a first electrode above the intermediate layer;
a light-emitting unit above the first electrode;
a partition wall adjacent to the light-emitting unit, and at least partially overlapping the connection electrode in plan view; and
an auxiliary electrode above the light-emitting unit, and electrically connected to the connection electrode.

2. The display device of claim 1, wherein the intermediate layer comprises one or more of silicon oxide (SiOx) or silicon nitride (SiNx).

3. The display device of claim 1, wherein the intermediate layer contacts the reflective electrode, and
wherein a side surface of the intermediate layer is surrounded by a side surface of the reflective electrode in plan view.

4. The display device of claim 1, wherein a surface of the intermediate layer and a surface of the connection electrode are at a same plane.

5. The display device of claim 1, wherein the reflective electrode and the connection electrode comprise a same material.

6. The display device of claim 5, wherein the reflective electrode and the connection electrode comprise silver (Ag).

7. The display device of claim 1, wherein the partition wall comprises a first partition wall layer, and a second partition wall layer above the first partition wall layer and protruding outwardly further than the first partition wall layer.

8. The display device of claim 7, wherein the second partition wall layer protrudes outwardly further from the first partition wall layer by about 0.3 μm to about 1 μm.

9. The display device of claim 7, wherein the first partition wall layer comprises aluminum (Al), and
wherein the second partition wall layer comprises titanium (Ti).

10. The display device of claim 7, wherein the light-emitting unit is separated from the partition wall, and does not contact the first partition wall layer.

11. The display device of claim 1, wherein the auxiliary electrode at least partially overlaps the connection electrode in plan view.

12. The display device of claim 11, wherein the auxiliary electrode comprises transparent conductive oxide (TCO) material.

13. The display device of claim 1, further comprising a second electrode above the light-emitting unit, and electrically connected to the partition wall by the auxiliary electrode.

14. The display device of claim 1, wherein the second trench has a second trench height, and
wherein the first trench has a first trench height that is lower than the second trench height.

15. The display device of claim 14, wherein a difference between the second trench height and the first trench height is about 500 Å to about 1000 Å.

16. A method of manufacturing a display device comprising:
forming an insulating layer defining a first trench and a second trench above a base layer;
forming a connection electrode at least partially located in the first trench;
forming a reflective electrode at least partially located in the second trench;
forming an intermediate layer above the reflective electrode;
forming a first electrode above the intermediate layer;
forming a partition wall above the connection electrode, and overlapping the connection electrode in plan view;
forming a light-emitting unit above the first electrode; and
forming an auxiliary electrode above the light-emitting unit, and electrically connected to the connection electrode.

17. The method of claim 16, wherein forming the reflective electrode, forming the connection electrode, and forming the intermediate layer comprise:
depositing a base reflective electrode above a base insulating layer;
depositing a base intermediate layer above the base reflective electrode; and
polishing at least a portion of the base insulating layer, the base reflective electrode, and the base intermediate layer, to form the reflective electrode, the connection electrode, and the intermediate layer.

18. The method of claim 17, wherein the polishing comprises polishing the base reflective electrode to form the reflective electrode and the connection electrode, and polishing the base intermediate layer to form the intermediate layer, and
wherein a surface of the intermediate layer and a surface of the connection electrode are at a same plane.

19. The method of claim 17, wherein the forming the partition wall on the connection electrode comprises:
forming a first partition wall layer above the connection electrode; and
forming a second partition wall layer above the first partition wall layer, and protruding outwardly further than the first partition wall layer.

20. The method of claim 17, further comprising forming a second electrode above the light-emitting unit, and electrically connected to the partition wall by the auxiliary electrode.
